(19) United States
(12) Patent Application Publication
(10) Pub. No.: US 2017/0146603 A1
(43) Pub. Date: May 25, 2017

(54) Integrated High And Low Voltage Ride Through Test System

(71) Applicants: State Grid Corporation of China, Beijing (CN); China Electric Power Research Institute, Beijing (CN)

(72) Inventors: Shiyao QIN, Beijing (CN); Ruiming WANG, Beijing (CN); Yong SUN, Beijing (CN); Shaolin LI, Beijing (CN); Chen CHEN, Beijing (CN); Jinping ZHANG, Beijing (CN)

(73) Assignees: State Grid Corporation of China, Beijing, BJ (CN); China Electric Power Research Institute, Beijing, BJ (CN); CEPRI ZHANGBEI WIND POWER RESEARCH AND TEST CO. LT D., Zhangjiakou (CN)

(21) Appl. No.: 15/313,460

(22) PCT Filed: May 22, 2015
(86) PCT No.: PCT/CN2015/079593

§ 371 Date: Nov. 22, 2016

(30) Foreign Application Priority Data
May 23, 2014 (CN) 201410222336.2

(51) Int. Cl. G01R 31/34; H02K 7/18; H02P 9/10

(52) U.S. Cl. CPC G01R 31/34; H02P 9/102; H02K 7/183

(57) ABSTRACT

An integrated high and low voltage ride through test system, comprising a primary system and a secondary system; the secondary system controls the primary system to realize information interaction, and is connected to a power grid and a wind generation set via an inlet wire switch cabinet and an outlet wire switch cabinet of the primary system; the integrated high and low voltage ride through test system actually simulates voltage drop and rise characteristics in a power grid failure, ensures that when generating a low voltage and a high voltage, the change of a voltage phase angle and power quality are consistent with actual power grid failure characteristics, and enables coherent low voltage and high voltage ride through capacity testing on the wind generation set in a primary test process. The test system employs a structural design of a mobile vehicle-mounted container, with all component modules thereof being integrally installed in a standard container, free from the impact of weather and geographical environment, being able to conduct all-weather on-site testing in any wind farm, and having good environment adaptability.

### RELATED APPLICATIONS

This application is a United States National Stage Application filed under 35 U.S.C 371 of PCT Patent Application Serial No. PCT/CN2015/079593, filed 2015 May 22, which claims Chinese Patent Application Serial No. 201410222336.2, filed 2014 May 23, the disclosure of all of which are hereby incorporated by reference in their entirety.

### FIELD OF THE INVENTION

The invention belongs to the field of new energy access and control technology, and particularly relates to an integrated high and low voltage ride through test system.

### BACKGROUND OF THE INVENTION

In recent years, with a rapid development of wind power industry in China, the wind power machine installation has an increasingly high proportion and a large scale wind farm power generation has also become the mainstream wind power development. Since the grid-connected wind turbine generator is installed in its run-time dependent access point network voltage holding unit self-voltage, the frequency and phase stability, power grid voltage stabilization of the wind turbine generator plays an important role in normal operation. When the power grid has experienced a transient failure, the voltage transient is reduced, when a grid fault is cleared, due to the large number of power grid reactive power compensation device could not timely exit, after the grid voltage recovery results highly susceptible to voltage increases, ie, when the power grid fails, the wind turbine machine end grid not only has the low voltage, high voltage and will successively appear 2012 Years of several severe wind power off-network, the fault of the grid voltage is sufficient to show that the wind farm/wind turbine operating in severely affected. 2012 In north China, for example, a wind farm grid three-phase short-time short circuit fault occurs, which result in a without low voltage ride-through capability wind turbine shut down all offline, a portion of with the low voltage ride-through capability wind turbine generator is successful “tunneled” in low voltage fault which could not offline continuous operation, in the subsequent grid voltage recovery process, the system reactive power compensation device fails to timely adjust or resection, due to the local power grid reactive power excess, grid overvoltage short-time fault occurred, so that a large number of successful “through” the low voltage fault of the unit due to power grid short-term high voltage failure and removal. Due to high voltage failure causes the offline unit even more than a low voltage fault during offline unit number. It is desired to ensure that the power grid has a transient fault, the wind park/wind turbine can still not offline continuous operation, at the same time the wind turbine is required to have a low voltage ride through (low voltage ride-through (LVRT),) capability and high voltage ride through (high voltage ride-through, HVRT) capability. To detect the ability, requiring special high and low voltage ride through detection device. Application No. 201220255118.5 discloses a mobile wind turbine generator high-low voltage ride-through testing device, provides a power grid while the high and low voltage analog scheme, the tap of the secondary winding of the transformer through the hopping of the wind generating set is reduced with the increase of the generator terminal voltage, the voltage drop and rise of wind turbine generator set are realized by winding tap change of transformer secondary winding, but the voltage waveform phase angle and power quality do not change during the voltage decrease and increase period, which is different from the actual grid fault. It cannot simulate an actual power grid failure fault voltage phase angle and power quality significant change, thus cannot detect the fault voltage phase angle and power quality significant change factors on high voltage ride through of the wind turbine generator and the low voltage ride through capability, thereby reducing the accuracy of the test. It is difficult to meet the wind turbine generator low voltage and high voltage ride through capability testing actual requirements.

### SUMMARY OF THE INVENTION

The present invention provides an integrated high-low voltage ride-through test system, a grid fault can be truly simulated voltage drop and rise characteristics in, ensuring the production of a low voltage and high voltage, the voltage phase angle and power quality variations and real power grid failure characteristic, in a test process of the wind turbine generator to develop a coherent low-voltage and high-voltage ride through capability detection. The test system employs a mobile vehicle-mounted container structure design, all modules are integrated in standard shipping containers, not limited by climate and geographical environment influence, can be used in any wind farm to develop all-weather field testing, has extremely high environmental adaptability.

### In Order to Achieve the Above Object, the Present Invention Adopts the Following Technical Solution:

The present invention provides an integrated high-low voltage ride-through testing system, the testing system comprises a primary system and a secondary system, the secondary system controls the primary system to realize information exchange, and via an incoming cable switch cabinet and an outgoing cable switch cabinet of the primary system that is respectively connected with a power grid and a wind turbine.

The primary system comprises a switch cabinet unit, a reactor unit and a capacitor unit; the switch cabinet unit comprises an incoming cable switch cabinet, a bypass switch cabinet K1, a short-circuit switch cabinet K2, a short-circuit switch cabinet K3 and an outgoing cable switch cabinet, the reactor unit comprises a current-limiting reactor X1 and short-circuit reactor X2, the capacitor unit comprises a reactive capacitor X3; the incoming cable switch cabinet, a bypass switch cabinet K1 and the outgoing cable switch cabinet are connected in series sequentially through a bus, the short-circuit switch cabinet K2 and the short-circuit switch cabinet K3 is connected to a bus between the bypass switch cabinet K1 and the short-circuit switch cabinet K3, the current limiting reactor X1 and bypass switch cabinet K1 are connected in parallel, the short-circuit reactor X2 and reactive capacitor X3 is respectively connected in series to the short circuit switch cabinet K2 and the short-circuit switch cabinet K3.

Between the short-circuit reactor X2 and the short-circuit switch cabinet K2, between the reactive capacitor X3 and the short-circuit switch cabinet K3 are respectively arranged a single-phase isolating switch.

The incoming cable switch cabinet, a bypass switch cabinet K1, a short-circuit switch cabinet K2, the short-circuit switch cabinet K3 and the outgoing cable switch cabinet are made of a mechanical switch or a semiconductor switch.

The current limiting reactor X1 and short-circuit reactor X2 are made of any one of an oil-immersed hollow reactor, an oil-immersed iron core reactor, a dry hollow reactor, a dry-type iron core reactor, a clamping type dry hollow reactor, a wrapping-type dry hollow reactor or a cement reactor.

The reactive capacitor X3 uses a reactive power generation device, wherein the reactive power generating device comprises a static var generator SVG, a thyristor switched capacitor bank TVC or mechanical switching capacitor set MSC.

The incoming cable switch cabinet, a bypass switch cabinet K1, a short-circuit switch cabinet K2, the short-circuit switch cabinet K3, the outgoing cable switch cabinet, the current-limiting reactor X1, the short-circuit reactor X2 and reactive capacitor X3 are all located in the same container to realize the high and low voltage ride through test system functionality and structural integrity.

The secondary system comprises a control system, a measuring system and a safety protection system;

The control system collects and verifies a test system of respective switches of the respective switch cabinet position state signal, and through a central processor performs logic judgment to confirm an operation state of the test system;

in a high-low-voltage ride-through test, the control system according to each of a switch cabinet action timing logic in turn transmits a remote control signal to each switch cabinet, an automatic control switch cabinet action switching reactor and a capacitor, and automatically complete the low voltage ride-through and high voltage ride through test;

the control system configuration of the remote monitoring system, so that remote monitoring of the test system, the test personnel safety.

the measuring system comprises a voltage transformer and a current transformer, the incoming cable switch cabinet and the outgoing cable switch cabinet are respectively provided with the voltage transformer, the test system access points for measuring the network voltage and the test point voltage; the incoming switch cabinet, the short-circuit switch cabinet K2, the short-circuit switch cabinet K3 and the outgoing cable switch are respectively arranged on the current transformer, a test system for measuring the incoming cable, the test point and the short-circuit point and each point current.

the safety protection system comprises the relay protection device, the infrared temperature measuring system, a signal lamp and a threshold switch;

the incoming cable switch cabinet and the outgoing cable switch are mounted on the relay protection device, when the test system is an abnormal voltage, current or frequency fails, the relay protection device will exit the test system to isolate fault points and ensure the operation safety of the power grid;

A current-limiting reactor X1, the short-circuit reactor X2 and reactive capacitor X3 are respectively provided with the infrared temperature measuring system to monitor operating temperature of the short-circuit reactor X1, X2 and reactive capacitor X3 in real time, to prevent the occurrence of the over-temperature fault;

A signal lamp is installed at an inlet of the container display the operation state of the test system in real time, while the door limit switch is installed when the operator opens the door in error, the door limit switch triggers emergency tripping systems, immediately disconnects the incoming cable switch cabinet and the outgoing cable switch cabinet, the test system is cut out from a power grid, to ensure test system and personnel safety.

Compared with the Closest Prior Art, the Present Invention has the Following Beneficial Effects:

(1) The present invention is the first time based on the combination of impedance circuit buck and capacitive reactive power injection boosting principle to realize the high voltage and low voltage integrated output design, the test system can be continuously complete the low voltage ride through and high voltage ride through a single test, the test function is complete, the test efficiency is extremely high;

(2) Based on short circuit pressure drop principle and the impedance of the capacitive reactive power injection boosting principle, it can be most truly simulated power grid faults occur successively in the voltage rise and drop characteristics, and, when the test system to generate a low voltage and a high voltage, its voltage amplitude, the phase angle and power quality variations and real power grid fault characteristic is consistent, thereby guaranteeing the accuracy of the test result;

(3) The use of mobile vehicle-mounted container structure design, all modules are integrated in standard shipping containers, not limited by climate and geographical environment influence, and can be used in any wind farm to develop all-weather field testing, has extremely high environmental adaptability.

### BRIEF DESCRIPTION OF THE DRAWINGS

FIG. 1 is a schematic diagram of integrated high and low voltage through test system;

FIG. 2 is a single-phase system schematic diagram of integrated high and low voltage ride through test system in an embodiment of the present invention;

FIG. 3 is a timing diagram of the test system testing process switching operation in an embodiment of the present invention;

FIG. 4 is a schematic diagram of a dry hollow reactor in an embodiment of the present invention;

FIG. 5 is a topology chart of reactive capacitor X3 branch in an embodiment of the present invention;

FIG. 6 is a system structure diagram of integrated high and low voltage ride through test system in an embodiment of the present invention;

FIG. 7 is an installation layout view of container of integrated high and low voltage ride through test system in an embodiment of the present invention;

FIG. 8 is a waveform diagram of AB-phase line voltage test data in real-time in an embodiment of the present invention;

FIG. 9 is a graph of AB-phase line voltage effective value of the test data in an embodiment of the present invention.

### DETAILED DESCRIPTION OF THE EMBODIMENTS

Embodiments of the present invention will be further illustrated in detail below in combination with the accompany drawings.

The present invention provides an integrated high-low voltage ride-through test system, the test system can be in a single experiment to generate consecutive engagement during a grid fault, low voltage and high voltage, can simulate the entire process of the grid voltage drops when a power grid short-circuit failure occurs, and then the grid voltage rise to recover to normal after the fault is cleared,

the phase of the voltage waveform and power quality variations can be simulated during the fault period, truly reflect the characteristics of the power grid voltage fault. The test system can be used in the field of a wind turbine generator set for consecutive connection of low voltage ride through and high voltage ride through test, detecting the low voltage ride through and high voltage ride through capability. The test system using a field test, the effect of the power grid in the relevant national standard range, meets the safe operation of a power grid. The test system employs a mobile vehicle-mounted container structure design, all of the component modules are integrated in a standard container, to realize the modular connection design, a convenient transportation, high testing the flexibility, and it is not limited by climate and geographical environment, can be carried out in any wind farm field test in all weather, has extremely high environment adaptability. The test system could realize low-voltage ride-through and high-voltage through the integrated design, with high system integration level, high reliability, and the highest economic and technical indexes; the test system is suitable for various types of on-site testing of wind turbine generator, achieving the requirements of Chinese and the European and American countries high and low voltage ride through test standard requirements of the test device, and with a the widely application range.

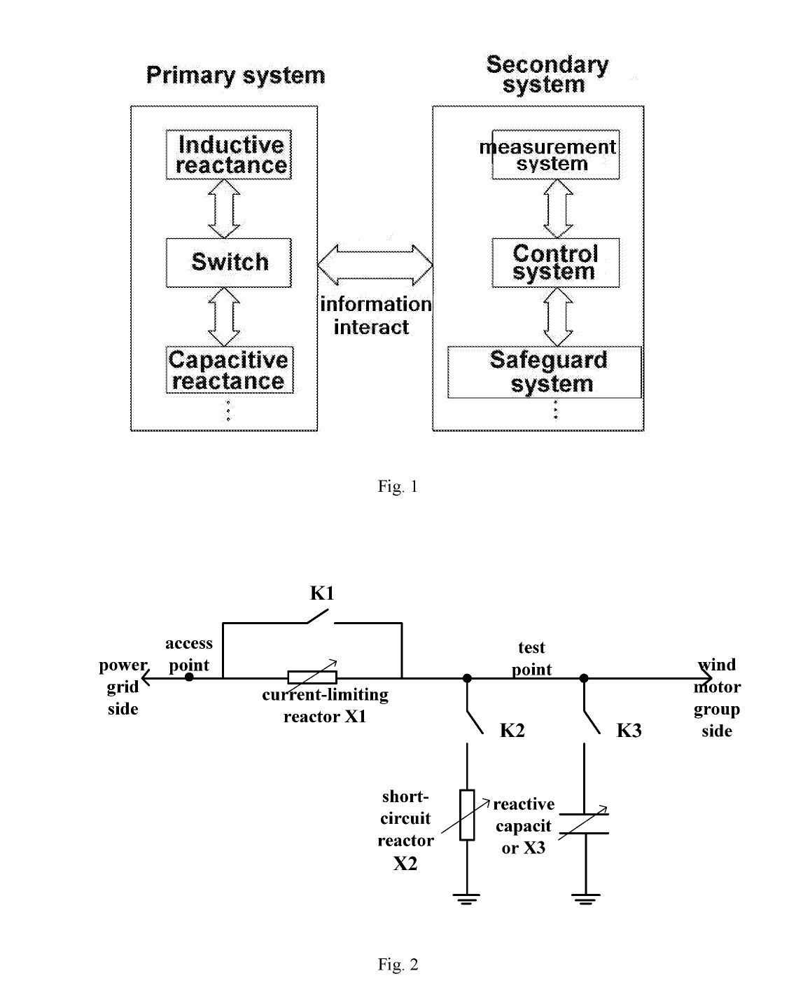

As shown in FIG. 1, the test system comprises a primary system and a secondary system, the secondary system controls the primary system to realize information exchange, and via an incoming cable switch cabinet and an outgoing cable switch cabinet of the primary system that is respectively connected with a power grid and a wind turbine generator connection.

The primary system comprises a switch cabinet unit, a reactor unit and a capacitor unit; the switch cabinet unit comprises an incoming cable switch cabinet, a bypass switch cable K1, a short-circuit switch cabinet K2, a short-circuit switch K3 and an outgoing cable switch cabinet, the reactor unit comprises a current-limiting reactor X1 and short-circuit reactor X2, the capacitor unit comprises a reactive capacitor X3; the incoming cable switch cabinet, a bypass switch cable K1 and the outgoing cable switch cabinet are connected in series sequentially through a bus, the short-circuit switch cabinet K2 and the short-circuit switch cabinet K3 is connected to a bus between the bypass switch cabinet K1 and the short-circuit switch cabinet K3, the current limiting reactor X1 and bypass switch cabinet K1 are connected in parallel, the short-circuit reactor X2 and reactive capacitor X3 is respectively connected in series to the short circuit switch cabinet K2 and the short-circuit switch cabinet K3.

Based on the short-circuit impedance voltage division principle, by closing the short-circuit switch cabinet K2 will put short-circuit reactor X2 into a primary system operation, the power grid caused by the short-circuit reactor X2 generates a controllable short-circuit; by opening the bypass switch cabinet K1 will put current limiting reactor X1 into a primary system operation, to limit the short-circuit current test, maintaining a system access point network voltage substantially constant. In the controllable short-circuit period, by the both short-circuit reactor X2 and current limiting reactor X1 partial pressure causes a voltage drop of the test point, the voltage drop depth is

$${U}_{t} = ( \frac{X 2}{X 1 + X 2 + X 0} ) * {U}_{n} ;$$

wherein, Uₙ and X0 respectively, to test the system access point system rated voltage and system impedance. By adjusting X1 and X2 of the input ratio, can alter the test point voltage drop depth, the voltage drop depth adjustment range of 0-100% Un, the adjustment step size may be determined based on the inductance value of the adjusted step length. The voltage drop duration time may be set freely by adjusting the closed duration time of the short-circuit switch cabinet K2.

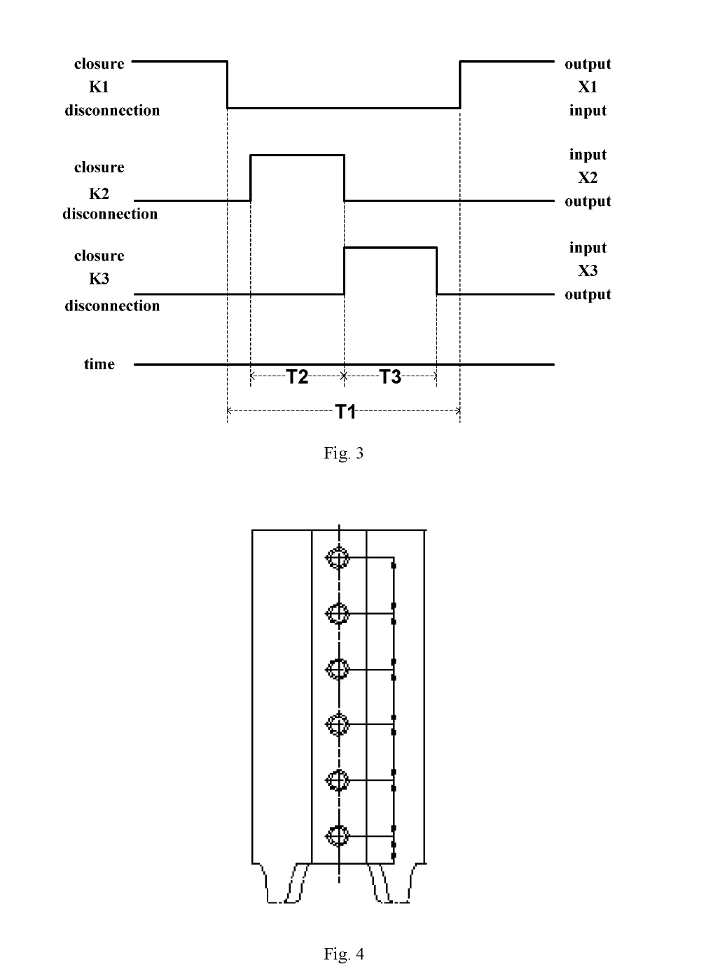

The test system high voltage generation scheme is based on a the principle of capacitive reactive power injection to improve voltage, in the current limiting reactor X1 put into operation, by closing the short-circuit switch cabinet K3 will be put reactive capacitor X3 into a primary system operation, a reactive capacitor X3 generates the capacitive current I_{c} flows from the test point flows through the current-limiting reactor X1 to a system access point, to produce a voltage difference ΔU access the current limiting reactor X1 point, because the test system is the system voltage remains substantially constant, so that the test point voltage Ut is raised, in the value of: Uₜ=Uₙ+ΔU. By adjusting the value of the current limiting reactor X1 and reactive capacitor X3 input impedance value, the test point voltage rise can be changed, the adjustment step size may be set freely based on the adjusted step length of the resistance value. A voltage increase duration time may be set freely by adjusting the closed duration time of the short circuit switch cabinet K3. The entire test system during a single test process to generate consecutive low voltage and high voltage, the switching timing as shown in FIG. 3 where T1 is the inductance of the current limiting reactor into a time length; T2 is short-circuit reactor X2 into a time length, ie, low voltage duration time; T3 is a reactive capacitor into a duration X3, the high voltage duration through the switch cabinet K1, K2, K3 closure timing control can be arbitrarily set to low voltage and high voltage duration, and may set both the continuation or interval of time occurs, but requires K1 must be in the off state allows closed K2, K3, and K2 and K3 are not simultaneously in the closed position.

Between the short-circuit reactor X2 and the shorting switch cabinet K2, between the reactive capacitor X3 and the short-circuit switch cabinet K3 are respectively arranged a single-phase isolating switch, by the isolating switch closing achieves to the corresponding single phase reactor or capacitor the connection to the switch cabinet, finally, the per-phase reactor or capacitor switching control alone.

The incoming cable switch cabinet, a bypass switch cabinet K1, a short-circuit switch cabinet K2, shorting switch cabinet K3 and the outgoing cable switch cabinet are mechanical switches (such as a switch cabinet, a circuit breaker, a contactor, etc.) or a semiconductor switch such as a (thyristor, GTO, IGBT, IGCT, etc.) the switch requires short-time actions ability and high breaking capacity and other characteristics. The switch model is selected according to the test system voltage level (medium pressure 66 KV or 35 KV, low pressure 690 V) and a test capacity (0.5 MW/1.5 MW/3 MW/6 MW). To 35 KV 3 MW integrated high and low voltage ride through test system for example, comprehensively considering the mobile container space and power factor, the switch can select a rated current of 1250 A SF6 gas insulated switchgear (GIS).

The cabinet-type all of the high-voltage charged portions are all closed in SF6 insulating gas tank, ensures that the high-voltage discharge phenomenon does not occur, the test system and sufficiently ensure the electrical safety tester, the volume of air-insulated switchgear ¼, the maximum degree of saving the installation space of the container.

The current limiting reactor X1 and short-circuit reactor X2 are made of oil-immersed hollow reactor, the oil-immersed iron core reactor, dry hollow reactor, a dry type iron core reactor, a clamping type dry hollow reactor, a wrapping-type dry hollow reactor and cement, any of the reactor; the test system is to increase the voltage drop or rise amplitude range, a plurality of different resistance values of the reactor or a single multi-tap (inductance value) reactor. At the same time can increase the inductance of the reactor in the fine adjustment function, improving the accuracy of the test system, test voltage. The inductance value of the reactor needs to be selected according to the voltage level of the test system and test capacity assessment. To 35 KV/3 MW integrated high and low voltage ride through test system for example, a comprehensive consideration of the mobile container space limitations and reactor impedance linear characteristics and other factors, a current-limiting reactor X1 and X2 selected short-circuit reactor with multi-tap dry hollow reactor, the shape structure as shown in FIG. 4, the reactor parameters as shown in table 1.

TABLE 1

| inductive | | inductance value | 50 Hz | resistance |
|---|---|---|---|---|
| reactance | tap | (mH) | equivalent resistance (Ω) | value (Ω) |
| K1 | 1-2 | 300 | 94.2 | 1.7 |
| | 2-3 | 150 | 47.1 | 0.7 |
| K2 | 1-2 | 40 | 12.6 | 0.2 |
| | 2-3 | 160 | 50.2 | 0.8 |
| | 3-4 | 950 | 298.3 | 3.5 |

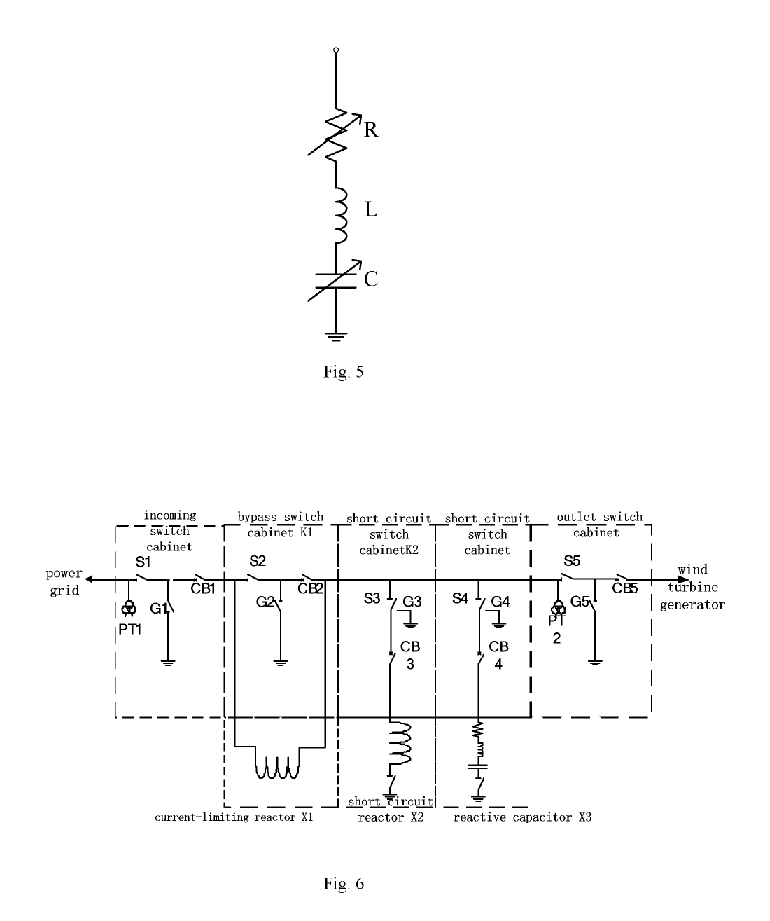

The reactive capacitor X3, a reactive power generation device, wherein the reactive power generating device comprises a static var generator SVG, a thyristor switched capacitor bank TVC or mechanical switching capacitor set MSC. The reactive capacitor X 3 branch of the basic topology as shown in FIG. 5, each branch is composed of a damping resistor, a current limiting reactance and a reactive capacitor three elements, wherein the capacitor C is used as the main functional component, its main role is to provide the system with a certain amount of capacitive reactive current, the current flow through the inductive reactance X1 to generate voltage differences, thereby lifting the test point voltage; a current-limiting reactor 1 is mainly to limit the short circuit current of the capacitor and the switching-on inrush current; the damping resistor R's primary function is to prevent the system current oscillation, reducing capacitor switching transient current and voltage transients. To 35 KV/3 MW integrated high and low voltage ride through test system for example, the short-circuit reactor X2 selected output tap provided with three sets of capacitor power capacitor group in parallel, the output parameters shown in table 2 below:

TABLE 2

| capacitor | capacitance | 50 Hz equivalent |
|---|---|---|
| grouping | (μF) | capacitive-reactance |
| #1 | 13 | 245 |
| #2 | 11 | 289 |
| #3 | 9 | 354 |

The integrated high and low voltage ride through test system for coherent low voltage ride through and high voltage ride through, by matching the different current limiting reactor X1, the short-circuit reactor X2 and reactive capacitor X3 input impedance value, different amplitude can be obtained by a low voltage and a high voltage waveform. In an actual test, to 35 KV power grid, the short-circuit capacity of the system, which is considered as 400 MVA system impedance of about 3Ω, the parameters of the 35 KV, 3 MW integrated high and low voltage ride through test system for a 3 MW wind turbine generator for low-voltage and high-voltage ride-through test, by matching the current limiting reactor X1 and short-circuit reactor X2 input value, may result in different depths of the voltage drop waveform; by matching the input value of the current limiting reactor X1 and reactive capacitor X3, can get a different magnitude of voltage rise waveform. The test system specific parameters match the voltage amplitude ratio and a test point such as shown in table 3;

TABLE 3

| | | | | | | | | Test |
|---|---|---|---|---|---|---|---|---|
| | | | | | | | Test | point |
| serial | InductanceX1 | | Inductance X2 | | Capacitance X3 | | point | amplitude |
| number | Inductance | Inductance | Inductance | Inductance | Capaci- | Capaci- | Voltage | of |
| — | L (mH) | value (Ω) | L (mH) | value (Ω) | tance C (μF) | tance (Ω) | Dip | pressure |
| 1 | 300 | 94.2 | 40 | 12.6 | 13 | 245 | 10% Uₙ | 129% |
| 2 | 150 | 47.1 | 40 | 12.6 | 13 | 245 | 20% Uₙ | 120% |
| 3 | 300 | 94.2 | 160 | 50.2 | 11 | 289 | 34% Uₙ | 121% |
| 4 | 150 | 47.1 | 160 | 50.2 | 11 | 289 | 49% Uₙ | 116% |
| 5 | 300 | 94.2 | 950 | 298.3 | 9 | 354 | 75% Uₙ | 114% |
| 6 | 150 | 47.1 | 950 | 298.3 | 9 | 354 | 87% Uₙ | 112% |

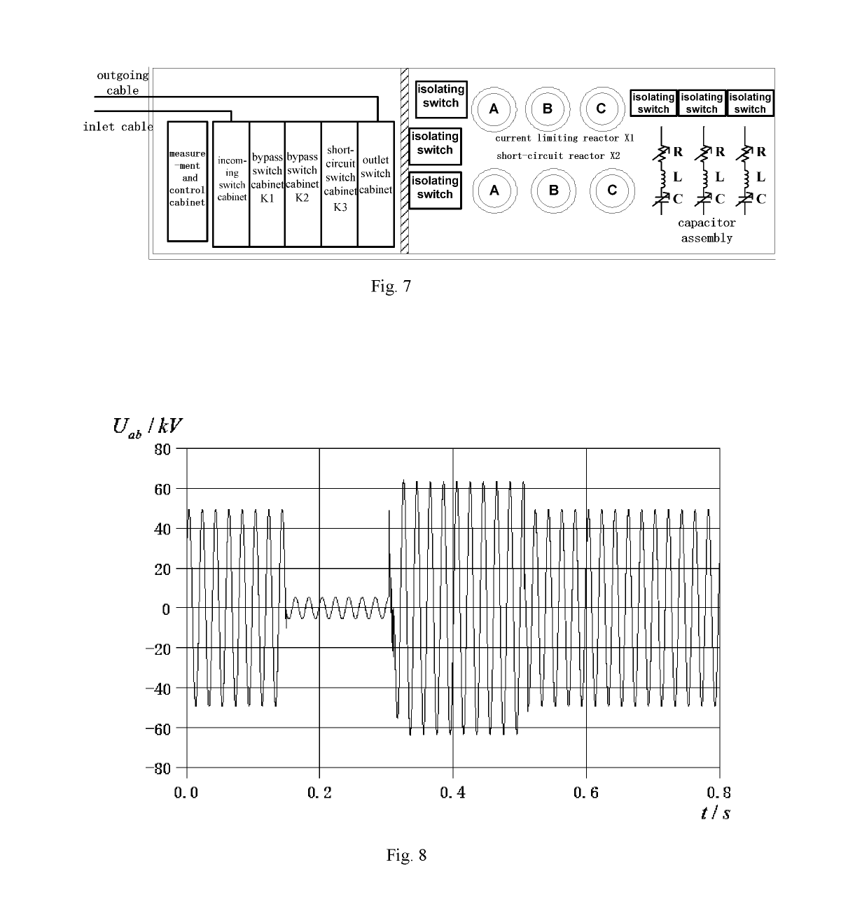

As shown in FIG. 7, the incoming switch cabinet, a bypass switch K1, the short-circuit switch K2, a short-circuit switch K3, the outgoing cable switch cabinet, a current-limiting reactor X1, the short-circuit reactor X2 and reactive capacitor X3 are all located in the same container, the high and low voltage ride through test system functionality and structural integrity.

The secondary system comprises a control system, a measuring system and a safety protection system;

The control system collects and verifies a test system of respective switches of the respective switch cabinet position state signal, and through a central processor performs logic judgment to confirm an operation state of the test system;

In a high-low-voltage ride-through test, the control system according to each of the switch cabinet action timing logic in turn transmits a remote control signal to each switch cabinet, the automatic control switch cabinet action switching reactor and a capacitor, and automatically complete the low voltage ride-through and high voltage ride through test;

Control system configuration of the remote monitoring system, so that remote monitoring of the test system, the test personnel safety;

The measuring system comprises a voltage transformer and a current transformer, the incoming cable switch cabinet and the outgoing cable switch cabinet are respectively provided with the voltage transformer, the test system access points for measuring the network voltage and the test point voltage; the incoming switch cabinet, a short-circuit switch cabinet K2, a short-circuit switch cabinet K3 and the outgoing cable switch are respectively arranged on the current transformer, a test system for measuring the incoming cable, the test point and the short-circuit point and each point current;

Safety protection system comprises the relay protection device, the infrared temperature measuring system, a signal lamp and a threshold switch;

The incoming cable switch cabinet and the outgoing cable switch are mounted on the relay protection device, when the test system is an abnormal voltage, a current or frequency fails, the relay protection device will exit the test the system, isolate the fault point, ensure safe operation safety of a power grid;

A current-limiting reactor X1, short-circuit reactor X2 and reactive capacitor X3 are respectively provided with the infrared temperature measuring system, the real-time monitoring of the current limiting reactor X1, the short-circuit reactor X2 and reactive capacitor X3 operating temperature, prevent the occurrence of an over-temperature fault;

The signal lamp is installed at an inlet of the container column, display a real-time test system operation state, the door limit switch is installed when the operator opens the door in error, the door limit switch triggers the emergency trip system, immediately disconnects incoming cable switch cabinet and outgoing cable switch cabinet, the test system is cut out from a power grid, so that test system and personnel safety.

### Embodiment

Using 35 KV/3 MW integrated high and low voltage ride through test system in the wind turbine generator for field test, the test system via a test cable is connected in series into a power grid and a tested wind generating set, test wiring schematic is shown in FIG. 8.

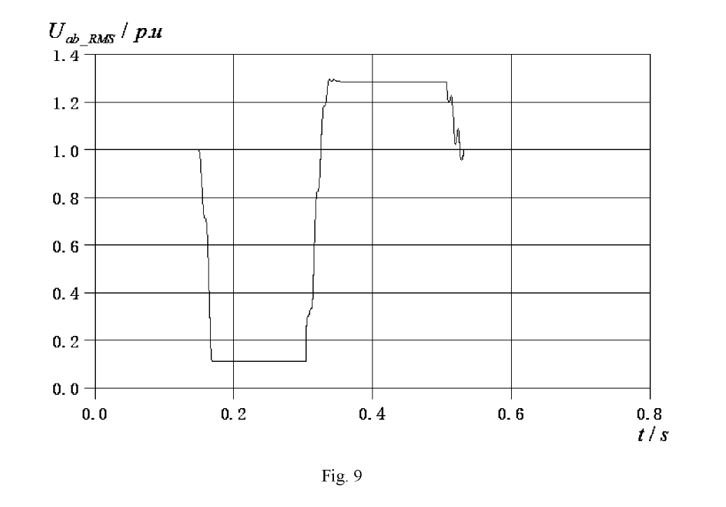

Development of on-site testing of the test system, the output performance and the test waveform as follows:
(1) Using a testing system for a three-phase symmetrical continuous low-voltage and high-voltage test, low voltage drop depth is set to 10% Un, a high voltage rising amplitude set to 130% Un. Test curve as shown in FIG. 8 and FIG. 9, in which, FIG. 8 is waveforms in real time for a voltage test point AB-phase line voltage of the test system, FIG. 9 is an effective value corresponding to the AB-phase line voltage, as shown in the test curve, the test system can be in one test period continuous low voltage ride through and high voltage ride through test, the output accuracy completely meets the test standard requirements.

Finally, it should be noted that the above-mentioned embodiments are merely used for illustrating the technical solutions of the present invention, rather than limiting them. Although the present invention has been described in detail with reference to the foregoing embodiments, those of ordinary skill in the art should understand that, they could still make modifications or equivalent substitutions to the embodiments of the present invention, and these modifications or substitutions, not departing from the spirit or scope of the present invention, shall fall within the scope of the claims of the present invention.

1. An integrated high-low voltage ride-through testing system, the testing system comprising:
a primary system and
a secondary control system, the secondary system control system configured to realize information exchange via a system inlet wire switch cabinet and an outlet switch cabinet that is connected with a power grid and a wind turbine is connected.

2. The integrated high-low voltage ride-through testing system of claim 1, wherein said integrated high and low voltage ride through test system comprises a switch cabinet unit, a reactor unit and a capacitor unit; the switch cabinet unit comprises an incoming switch cabinet, a bypass switch K1, a short-circuit switch cabinet K2 and an outgoing line of the switch cabinet, the reactor unit comprises a current-limiting reactor X1 and X2 short-circuit reactor, the capacitor unit comprises a reactive capacitor X3; the incoming switch cabinet, a bypass switch K1 and the outgoing line switch connected in series sequentially through a bus, the short-circuit switch K2 and the short-circuit switch K3 is connected to the bypass switch K1 and an outgoing bus between the switch cabinet, the current limiting reactor X1 and bypass switch K1 in parallel, the short-circuit reactor X2 and reactive capacitor X3 is respectively connected with the short circuit switch K2 and the short-circuit switch K3 are connected in series.

3. The integrated high-low voltage ride-through testing system of claim 2, wherein said integrated high and low voltage ride through test system, the short-circuit reactor X2 and the short-circuit switch K2, a reactive capacitor X3 and the short-circuit switch K3 are respectively arranged between a single-phase isolating switch.

4. The integrated high-low voltage ride-through testing system of claim 2, wherein said integrated high and low voltage ride through test system, the incoming switch cabinet, a bypass switch K1, a short-circuit switch cabinet K2, the short-circuit switch K3 and the outgoing line switch cabinet are made of a mechanical switch or a semiconductor switch;
the current limiting reactor X1 and short-circuit reactor X2 are made of an oil-immersed hollow reactor, the oil-immersed iron core reactor, dry hollow reactor, a dry-type iron core reactor, a clamping type dry hollow reactor, a wrapping-type dry hollow reactor and cement in a reactor;
the reactive capacitor X3, a reactive power generation device, wherein the reactive power generating device comprises a static var generator SVG, a thyristor switched capacitor bank TVC or mechanical switching capacitor set MSC.

5. (canceled)

6. The integrated high-low voltage ride-through testing system of claim 2, wherein the integrated high and low voltage ride through test system is characterized by: the incoming switch cabinet, a bypass switch K1, a short-circuit switch cabinet K2, the short-circuit switch K3, the outgoing line switch cabinet, a current-limiting reactor X1, the short-circuit reactor X2 and reactive capacitor X3 are all located in the same container, the high and low voltage ride through test system functionality and structural integrity.

7. The integrated high-low voltage ride-through testing system of claim 2, wherein the integrated high and low voltage ride through test system is characterized by: the secondary system comprises a control system, a measuring system and a safety protection system;

8. The integrated high-low voltage ride-through testing system of claim 2, wherein the integrated high and low voltage ride through test system is characterized by:
the control system collects and verifies a test system of respective switches of the respective switch position state signal, a central processor performs logic judgment, confirming an operation state of the test system;
High-low-voltage ride-through test, the control system according to each of a switch cabinet action timing logic in turn transmits a remote control signal to each switch cabinet, an automatic control switch cabinet action switching reactor and a capacitor, and automatically complete the low voltage ride-through and high voltage ride through test;
control system configuration of the remote monitoring system, so that remote monitoring of the test system, the test personnel safety.

9. The integrated high-low voltage ride-through testing system of claim 2, wherein the integrated high and low voltage ride through test system is characterized by: the measuring system comprises a voltage transformer and a current transformer, the inlet wire switch cabinet and an outlet switch are respectively provided with the voltage transformer, the test system access points for measuring the network voltage and the test point voltage; the incoming switch cabinet, a short-circuit switch K2, a short-circuit switch K3 and the outgoing line switch are respectively arranged on the current transformer, a test system for measuring the incoming line, the test point and the short-circuit point and each point current.

10. The integrated high-low voltage ride-through testing system of claim 7, wherein the integrated high and low voltage ride through test system is characterized by: the safety protection system comprises a relay protection device, the infrared temperature measuring system, a signal lamp and a threshold switch; the inlet wire switch cabinet and an outlet switch are mounted on the relay protection device, when the test system is an abnormal voltage, current or frequency fails, the relay protection device will test the system exits, an isolation fault points and ensure the operation safety of the power grid; a current-limiting reactor X1, the short-circuit reactor X2 and reactive capacitor X3 are respectively provided with the infrared temperature measuring system, the current limiting reactor is monitored in real time, the short-circuit reactor X1 X2 and reactive capacitor X3 operating temperature, to prevent the occurrence of the over-temperature fault signal lamp is installed at an inlet of the container; and the real-time display column, the operation state of the test system, while mounting the door limit switch when the operator error when opening the door, a door limit switch trigger emergency tripping systems, immediately disconnect the incoming switch cabinet and a wire outlet switch cabinet, the test system is cut out from a power grid, so that test system and personnel safety.
